(19) United States
(12) Patent Application Publication
(10) Pub. No.: US 2014/0353158 A1
(43) Pub. Date: Dec. 4, 2014

(54) DEVICE AND METHOD FOR CONTROLLED ADHESION UPON MOIST SUBSTRATE

(71) Applicant: Universita Campus Bio-Medico di Roma, ROMA, RM (IT)

(72) Inventors: Dino Accoto, Andrano (IT); Maria Teresa Francomano, Roma (IT); Caterina Esposito, Roma (IT)

(21) Appl. No.: 14/374,205

(22) PCT Filed: Jan. 24, 2013
(86) PCT No.: PCT/IB2013/050601

§ 371 Date: Jul. 23, 2014

(30) Foreign Application Priority Data
Jan. 24, 2012 (IT) RM2012A000026

(51) Int. Cl. B81B 1/00

(52) U.S. Cl. CPC B81B 1/002
USPC 204/451; 204/601

(57) ABSTRACT

A device for generating an adjustable adhesion force on a wet substrate is described. The device has a main body with an adhesion surface which, in use, arranges itself facing the substrate, at such adhesion surface the main body having a plurality of channels generating a capillary return for water present on the substrate. A delivery and/or reservoir system for silicone oil, providing the latter at the adhesion surface, so that silicone oil arranges itself interposed between the surface itself and the water on the substrate. A static electric field generating system generates a static electric field at the adhesion surface. Such electric field modifies the wettability of silicone oil with respect to the adhesion surface.

### TECHNICAL FIELD OF THE INVENTION

The present invention refers to a device for generating an adjustable adhesion force on a wet substrate, for instance in order to provide a control of the forces ,allowing locomotion on the latter of machines or other devices, or for a displacement or a manipulation of the substrate itself.

### BACKGROUND

Locomotion on a moist substrate and manipulation (e.g., lifting, translation, release) of items surrounded by moist surfaces require that, between surfaces in contact (e.g., between manipuland and manipulator), adequate adhesion forces be established and that the intensity of such forces be capable of being modulated.

For instance, in the bioengineering field such a requirement might be related to intracorporeal navigation of robots that move by exchanging forces with biological tissues with which they are in contact (e.g. gastrointestinal tract mucosae or the peritoneum surface). in the bioengineering field, such a requirement is related to the need to manipulate moist substrates of small-size objects, such as components of microelectro-mechanic systems. Said need may arise in industrial contexts for performing microassembling tasks, or tasks of pick-and-place type. In this latter application scenario, the moist surface is generally that of the manipulator.

The devices and methods used in the above-cited application fields entail limitations linked to the reduced possibility of controlling the adhesion force transmitted through the moist interface.

In the case, e.g., of the locomotion devices and techniques known in endoscopy, these did not satisfactorily solve the problem of control of device adhesion on the substrate, as instead necessary in order to be able to apply to the substrate itself a force suitable to produce the locomotor thrust.

Also as a consequence of this, in known devices for the generation of adhesion forces—and particularly in those for biomedical use—there are generally found:
high mechanical complexity, which in turn prevents a radical miniaturization of the components, needed instead for numerous intracorporeal applications;
low intrinsic safety, as the adhesion force can be generated through mechanic or pneumatic systems potentially capable of inflicting traumas or to microtraumas to biological tissues;
low level of controllability of the adhesion force;
high manufacturing and assembly costs.

Always by way of example, in the field of manipulation systems, it is found that mechanic-type conventional manipulators run the risk of deforming and/or damaging manipulated components in case they are particularly delicate; such a problem is found, e.g., in the field of miniaturized componentry manipulation.

On the contrary, capillary forces can be exploited to obtain grip forces that are firm but not excessively oversized with respect to the weight of the manipulated component. Capillary micromanipulators exploit lifting forces of capillary bridges that form between two moist solid surfaces. One of the limitations of this type of lifters is that the adhesion force depends on the geometry of the liquid bridges and therefore generally decreases once the manipulated component has been lifted. Moreover, the control of the capillary force is generally of ON-OFF type, as the electro-induced necking down of the capillary bridges below a critical diameter entails their breakage and therefore manipuland detachment.

### SUMMARY OF THE INVENTION

The present invention provides a device and a method allowing to obtain an adhesion capable of being modulated on a moist substrate, obviating some problems such as, e.g., those mentioned above in the field of locomotion and micromanipulation.

Control of adhesion on a moist substrate is obtained by a device according to claim 1 and, according to the same inventive concept, by a method according to claim 12.

Preferred features of the present invention are set forth in the dependent claims thereof.

In the present context, by “moist substrate” it is meant a generally solid to substrate having a liquid, for instance an aqueous solution, on its surface. Hence, also a wet or liquid-imbibed substrate falls within the meaning of “moist”.

The present invention provides some relevant advantages. The main advantage lies in that it enables to obtain an optimal adhesion, and therefore an optimal friction, on the wet substrate, both to the ends, e.g., of a locomotion and of the grip on the substrate itself. Moreover, such adhesion is capable of being modulated depending on contingent needs relative to the specific application.

Further advantages, features and the modes of employ of the present invention will be made evident in the following detailed description of some embodiments thereof, given by way of example and not for limitative purposes.

### BRIEF DESCRIPTION OF THE FIGURES

Reference will be made to the figures of the annexed drawings, wherein:

FIG. 1 shows a schematic illustration, in a cross section, of the mechanism of the so-called “wet adhesion” involving two fluids, in particular two liquids;

FIG. 2 schematically illustrates, in a cross section, the phenomenon of the so-called “electrowetting”, in which the angle of wettability of a liquid on a solid substrate is varied by the applying of a voltage;

FIGS. 3A to 3B show each a schematic view, in a cross section, of a device according to a preferred embodiment of the invention, during the applying of an electric field that progressively decreases the adhesion force at the interface of the device with a moist surface; and

FIG. 4 shows an enlarged detail of FIG. 3B, in which the electric field lines and the corresponding polarization of an adhesion surface of the device are exemplarily shown.

### DETAILED DESCRIPTION OF PREFERRED EMBODIMENTS

Preliminarily to the detailed description of preferred embodiments of the device of the invention, the theoretical bases of the invention itself are illustrated hereinafter.

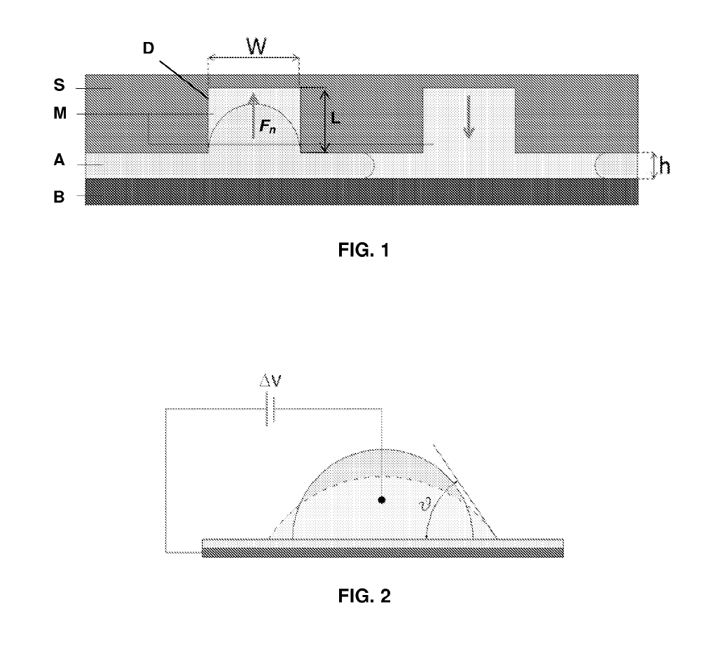

FIG. 1 schematically illustrates the principle of the so-called “wet adhesion”, present in nature and used, e.g., by some Amphibians belonging to the Ranidae family for stationing on a wet substrate.

In said figure a movable surface S is shown—corresponding, in said example, to the bottom part of the amphibian legs—bearing surface discontinuities D, shown purely by way of example in the form of channels of defined and regular geometry, but that in nature are of irregular geometry.

The movable surface S generates a mucus M and rests on a moist external surface or substrate B, the latter in particular wet by a liquid A, typically water.

Wet adhesion of the movable surface S on the external surface B is regulated, in the example considered, by controlling the discharge of mucus M and therefore, ultimately, the capillary return of water A within the discontinuities D.

Said phenomenon is described by equations:

$$Δ p = 2 γ ( \frac{1}{h} - \frac{1}{W} )$$

$$and$$

$${F}_{n} = Δ pbW = 2 γ bW ( \frac{1}{h} - \frac{1}{W} )$$

wherein:
Δp defines the pressure difference at the mucus M—water A interface between the two fluids;
Fₙ represents the normal force at the mucus M—water A interface, returning the water meniscus A within the discontinuity D;
γ represents the coefficient of surface tension at said interface between fluids A and M;
W represents the width of the channel D;
h represents the distance between the movable surface S and the external surface B; and
b defines the longitudinal dimension (depth) of the discontinuity, in a direction orthogonal to the cross section illustrated in FIG. 1.

FIG. 2 schematizes the phenomenon known as “electrowetting”, showing how the wettability of a fluid with respect to a surface—the latter solid or it also fluid—may be varied by the applying of an electric voltage.

In particular, the angle of wettability, θ, illustrated in FIG. 2, varies with the applying of an electric potential. In the example shown, said angle θ increases with the applying of the potential (ΔV), and therefore decreases the wettability proper of the fluid on the surface. Of course, it is also possible to produce an opposite effect, i.e. decrease the angle of contact (increase the wettability) by applying an appropriate potential.

The electrowetting phenomenon is linked to the variation of the coefficient of surface tension (γ) of the liquid-air interface following the applying of a potential (V). Such variation is described by the so-called Lippmann equation:

$${( \frac{\partial γ}{\partial V} )}_{p , T , μ} = - σ$$

wherein:
p, T and μ respectively represent pressure, temperature and chemical potential; and
σ is the charge density on the surface of the liquid.

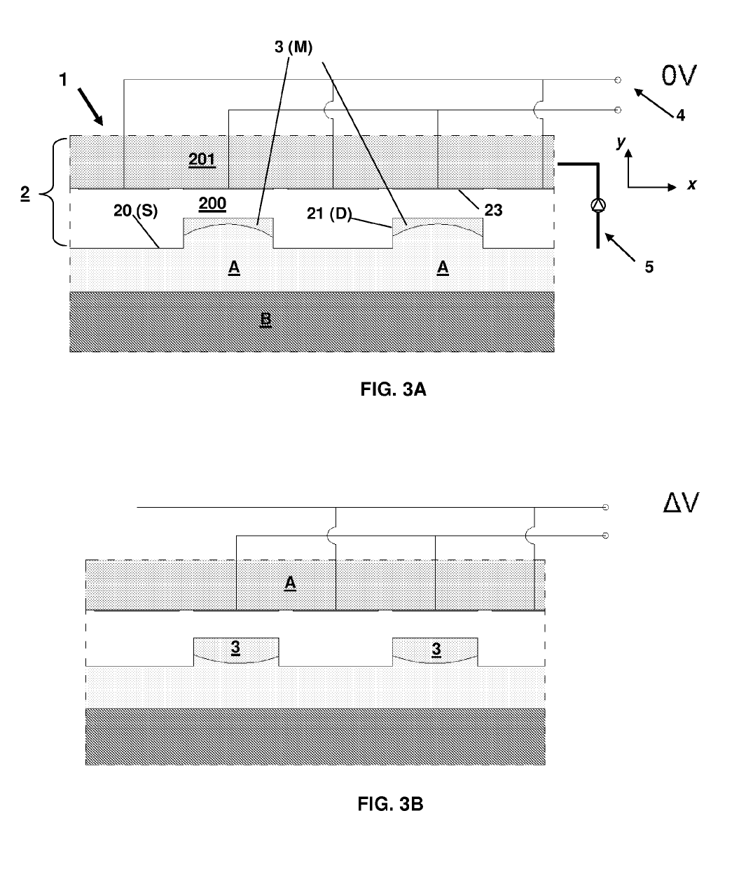

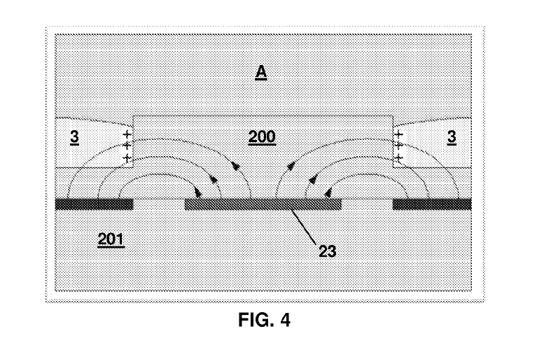

In the embodiment of the invention described hereinafter, referring to FIGS. 3A and 3B, the wettability of an interface liquid on a surface—corresponding respectively to the mucus M and the movable surface S in the above—considered example, with reference to FIG. 1—is modified, and in particular decreased, by the applying of an electric field. The varied wettability of said interface fluid entails a modification in the capillary return of a substrate liquid within the surface—liquid and substrate corresponding respectively to water A and to the external surface B in the example of FIG. 1.

Referring initially to FIG. 3A, a device apt to generate an adjustable adhesion force on a substrate or moist surface B according to a preferred embodiment of the invention is generally denoted by 1.

The substrate B is, as mentioned above, moist, bearing in particular a liquid, which will be referred to as substrate liquid A. In the present example, the device 1 may be construed as part of a robotic capsule equipped with a locomotion system for navigation in the intestine. In these particular cases, the substrate B can represent the intestinal wall, or mucosa, and the substrate liquid A the mucosa-secreted mucus, respectively.

The device 1 comprises a main body generally denoted by 2, bearing a surface 20, which will be referred to as adhesion surface and that corresponds to the movable surface S of the example of FIG. 1, illustrated above.

The adhesion surface 20, in use, arranges itself facing the substrate B.

The adhesion surface 20 bears a plurality of recesses 21, corresponding to the discontinuities D of FIG. 1, each apt to generate a capillary return for the substrate fluid A. In the present example such recesses 21 are in the form of channels extending the one parallel to the other one along the longitudinal to development of the adhesion surface 20, i.e. orthogonally to the plane of the cross-section shown in FIG. 3A.

As already in the example of. FIG. 1, each channel has a cross section of substantially rectangular shape. The planar dimensions of said cross section are denotable with L and W and develop respectively along an axis y, defining a is normal direction of approach of the adhesion surface 21 to the substrate surface B, and along a direction x orthogonal thereto.

Preferably, the main body 2 has a first adhesion portion 200, bearing precisely the adhesion surface 21, and a second support portion 201, fixed to the first portion 200 and transversally side-by-side thereto along the above-defined direction y.

Preferably, the first portion 200 of the main body 2 is made of polymeric material, e.g. polydimethylsiloxane (PDMS).

Electrodes 23 for the applying of an electric field are arranged at the interface between the two portions 200 and 201 of the main body 2. In the present example, each electrode 23 is of flat configuration, with a rectangular plan. The electrode 23 extends longitudinally in the main body 2, at and parallelly to a respective channel 21 or at and parallelly to the projection interposed between contiguous channels. Always in the present example, the electrodes 23 are equidistant the one from the other along direction x and have a regular arrangement. Preferably, the electrodes 23 are of noble metal, e.g. platinum.

The electrodes 23 are part of electric field generating means, generally denoted by 4. In the present example, such means 4 is suitable to generate a static electric field, with potential difference, adjustable according to specific adhesion needs, as will be illustrated in greater detail shortly.

The device 1 further comprises fluid delivery and/or reservoir means, generally denoted by 5 and only schematically shown in FIG. 3A. The delivery and/or reservoir means 5 is apt to provide an interface fluid 3 at the adhesion surface 20, so that said fluid, in use, arranges itself interposed between the adhesion surface itself and the substrate fluid A. The interface fluid 3 therefore to corresponds to the mucus M of the example of FIG. 1. Preferably, the delivery and/or reservoir means is obtained by capillary confining of the related fluid, e.g. at the recesses 21 of the surface 20.

In more general terms, fluid delivery and/or reservoir means may be provided, apt to ensure the presence of the aforesaid interface fluid 3 at the adhesion surface 20. In a particularly advantageous embodiment of the invention, the interface fluid 3 is a silicone oil.

Exemplary dimensions of the various component of the device 1 are indicated in the following, with reference to FIGS. 3A and 3B.
Substrate 201—surface area (76×24) mm²; thickness (y direction) 1.1 mm.
Electrodes 23—length (longitudinal direction orthogonal to that of the section of FIG. 3A and 3B)=15.5 mm, thickness (y direction)=20 nm, width (x direction)=150 μm.
Adhesion layer 200—covers an area equal to (45×15) mm²; in particular, each channel has a length (longitudinal direction orthogonal to that of the section of FIGS. 3A and 3B)=15 mm, a width (VV)=150 μm and a height (L)=50 μm; the residual thickness of the layer at each channel is of 50 μm (at the channel walls, the polymer has an overall thickness=100 μm).
substrate liquid M—the substrate 200 is coated with 0.1 ml of substrate liquid M, preferably silicone oil.

Silicone oils have the following preferred properties: i) availability of wide ranges of kinematic viscosity; and ii) good wettability in comparison with the substrate 200, e.g. attained by way of their chemical affinity.

With the above-indicated dimensional and tribological data, a preferred static electric field envisages the applying of a potential difference of about 60 V at the ends of adjacent electrodes 23, as shown in FIG. 3A.

The modes of employ of the device 1 described hereto will presently be illustrated.

In FIG. 3A, the device 1 is shown in the configuration in which there is no electric field applied. The adhesion surface 20 is at an exemplary distance h from the substrate B. The distance h will have a maximum value of the order of the tens of micron.

Under such circumstances, the silicone oil 3 has high wettability with respect to the adhesion surface 20, as is inferred by the angles of wettability shown. In particular, the meniscus of the silicone oil 3 has a substantially concave profile.

Under said condition, the substrate fluid A is returned by capillarity within the channels 21. Therefore, the “wet adhesion” phenomenon is established, in which a normal adhesion force (Fₙ) is established at the interface between the two fluid phases, silicone oil 3—substrate liquid A.

In FIG. 3B, the device 1 is shown with the applying of an electric field corresponding to a potential difference ΔV. Under said condition, the angle of wettability of the silicone oil 3 with respect to the adhesion surface 20 increases, i.e. the wettability of the surface 20 reduces. The variation of curvature of the meniscus produces an effect on the intensity of the normal force Fₙ. In the illustrated case, tends to decrease.

Referring to the example of use of the device 1 in intracorporeal locomotion, the adhesion condition of FIG. 3A enables to exert a firm grip of the device 1 on the biological tissue, e.g. on the intestinal mucosa, to the ends of a controlled stop or slowing down.

In the next step, shown in FIG. 3B, the device can detach from the tissue to advance in the body, e.g. driven by peristaltic waves.

A possible advantageous application of the device 1, in the field of intracorporeal locomotion, would see it employed on the rotatable members of the locomotion device according to the “pinch locomotion” principle of which at the Italian Pat. Appln. No. RM2009A000635.

On the basis of a hereto-mentioned variant embodiment, the device of the invention may envisage that the electric field be applied to produce an increase rather than a decrease of wettability of the interface fluid on the adhesion surface. Said variant may envisage the use of a suitable combination of materials for the manufacturing of the moist and adhesion substrates, as well as for the fluid 3.

Moreover, referring to the use of the device 1 for robot locomotion, the possible application thereof in industrial contexts different from the above-mentioned biomedical ones, e.g. for navigation in artificial or natural ducts or lumens, is highlighted.

The device is also particularly suitable for underwater use or for development of end effectors of manipulators.

As mentioned above, the invention further provides a method for generating an adjustable adhesion force between an adhesion surface as defined above and a wet substrate, mutually facing. The method proposed mainly comprises:
providing a plurality of recesses, as those defined above, on the adhesion surface, which are apt to generate a capillary return for a substrate fluid as introduced above;
providing an interface fluid at the adhesion surface, so that this interface fluid, in use, arranges itself interposed between the adhesion surface and the substrate fluid; and
selectively generating an electric field at the adhesion surface, so as to modify the wettability of the interface fluid on the adhesion surface.

The preferred features of the method have already been illustrated above with to reference to the device 1 and its variants.

The present invention has been hereto described with reference to preferred embodiments thereof. It is understood that other embodiments might exist, all falling within the concept of the same invention, as defined by the protective scope of the claims hereinafter.

1. A device for generating an adjustable adhesion force on a wet substrate, in particular in order to provide a locomotion of the device or a manipulation of the substrate, comprising:
a main body having an adhesion surface which, in use, is arranged facing the substrate, wherein at such adhesion surface said main body has a plurality of recesses apt to generate a capillary return for a substrate fluid present on the substrate;
fluid delivery and/or reservoir means, apt to provide an interface fluid at said adhesion surface, so that the interface fluid, in use, is arranged interposed between the adhesion surface and the substrate fluid; and
electric field generating means, apt to generate an electric field at the adhesion surface, so as to modify the wettability of the interface fluid on said adhesion surface.

2. The device according to claim 1, wherein the adhesion surface has a plurality of channels extending longitudinally thereon.

3. The device according to claim 2, wherein the channels have a substantially squared cross-section, preferably rectangular.

4. The device according to claim 2, wherein the normal section of each channel has the following dimensions: depth L=about 50 μm and width W=about 150 μm.

5. The device according to claim 1, wherein the electric field generating means comprises a plurality of electrodes, preferably of noble metal, housed within the main body, wherein the electrodes preferably have a flat configuration, preferably with a rectangular plan.

6. The device according to claim 5, wherein the electrodes have a regular arrangement.

7. The device according to claim 1, wherein the electric field generating means is apt to generate a static electric field.

8. The device according to claim 1, wherein the main body is made, at least at said adhesion surface, of polydimethylsiloxane (PDMS).

9. The device according to claim 1, wherein the main body is made, at least at a portion supporting said adhesion surface, of glass or other dielectric material, such as polymers.

10. The device according to claim 1, wherein the interface fluid is a silicone oil.

11. The device according to claim 1, wherein the applying of the electric field produces a variation of wettability of said interface fluid on the adhesion surface.

12. A method for generating an adjustable adhesion force between an adhesion surface and a wet substrate mutually facing, for instance to the ends of a locomotion of a navigation and/or manipulation device bearing such adhesion surface, which method comprises:
providing a plurality of recesses on said adhesion surface, which recesses are apt to generate a capillary return for a substrate fluid present on the latter;
providing an interface fluid at said adhesion surface, so that said interface fluid, in use, arranges itself interposed between the adhesion surface and the substrate fluid; and
selectively generating an electric field at the adhesion surface, so as to modify the wettability of the interface fluid on the adhesion surface.

13. The method according to claim 12, wherein on the adhesion surface a plurality of channels is provided, arranged along a geometric regular pattern.

14. The method according to claim 12, wherein the generation of a static electric field is provided.

15. The method according to claim 12, wherein the interface fluid is a silicone oil.

16. The method according to claim 12, wherein the applying of the electric field produces a decrease or an increase of wettability of said interface fluid on said adhesion surface.
